(19) United States
(12) Patent Application Publication
(10) Pub. No.: US 2010/0308496 A1
(43) Pub. Date: Dec. 9, 2010

(54) METHOD OF MANUFACTURING STAMPER

(75) Inventor: Shinji UCHIDA, Nagano (JP)

Correspondence Address: ROSSI, KIMMS & McDOWELL LLP., 20609 Gordon Park Square, Suite 150, Ashburn, VA, 20147, US

(73) Assignee: FUJI ELECTRIC DEVICE TECHNOLOGY CO., LTD, Tokyo (JP)

(21) Appl. No.: 12/719,526

(22) Filed: Mar. 8, 2010

(30) Foreign Application Priority Data
Jun. 9, 2009 (JP) 2009-138202

(51) Int. Cl. G03F 7/20; B29C 33/40

(52) U.S. Cl. 264/220; 430/296

(57) ABSTRACT

A method of manufacturing a stamper for nanoimprinting is provided which enables formation of finer patterns and which can be executed inexpensively. The method includes a step of forming a metal thin film on the surface of a substrate; a step of forming a resist layer on the surface of the metal thin film; a step of forming a relief pattern in the resist layer in use of an electron beam lithography method; a step of etching the metal thin film in imitation of the relief pattern in the resist layer, and forming a pattern-shaped metal mask; and, a step of forming a relief pattern on the substrate in imitation of the metal mask. In step (d), by side-etching the metal thin film, the width of the protruding portions formed in the substrate in step (e) are reduced to be less than the width of the depression portions of the relief pattern formed in step (c).

### BACKGROUND

The invention relates to a method of manufacturing a stamper for nanoimprinting.

With the rising integration levels of information recording media and semiconductor devices, technology for formation of finer patterns in resist layers formed on the surfaces of substrates has been sought for use in manufacturing of information recording media and semiconductor devices.

In the prior art, photolithography methods have long been used as methods for forming fine patterns in resist layers. Photolithography methods are methods in which a resist layer is exposed to light, forming an exposure pattern (latent image) in the resist layer, and development treatment of the resist layer is then performed to form a patterned resist layer on the substrate.

In order to form more finely patterned resist layers, the wavelength of the light used in exposure has gradually been shortened. In order to form fine resist patterns of 100 nm or below, an EB lithography method, in which an electron beam (EB) is used in place of light for exposure, has been developed. However, there are problems with applying the EB lithography method to mass production processes. Problems in EB lithography include the high cost of equipment, and the time required for pattern drawing, so that throughput is low.

In recent years, a nanoimprinting method has been developed as a method of efficiently forming fine patterns. For example, as one type of nanoimprinting method, a thermal nanoimprinting method, accompanied by the application of a temperature cycle, has been proposed (see for example U.S. Pat. No. 5,772,905). In the thermal nanoimprinting method, a stamper on which a relief pattern has been formed is pressed against a resist layer formed on the surface of a substrate in a heated state, and while maintaining the pressed state, the resist layer is cooled, after which the stamper is released from the resist layer, to transfer the relief pattern to the resist layer.

In the method described in U.S. Pat. No. 5,772,905, first a silicon oxide film is formed on the surface of a silicon substrate, and a relief pattern is formed in the silicon oxide film using for example an EB lithography method, to prepare a stamper. On the other hand, spin coating or similar is used to form a resin film, for example of polymethyl methacrylate (PMMA), on the surface of a substrate. Next, heating is performed to a temperature at or above the glass transition temperature (Tg) of the resin film (200° C. for PMMA, with Tg=105° C.) to soften the resin film, and the stamper is pressed with a pressure of 13 MPa against the softened resin film. Next, with the stamper in the pressing state, the resin film is cooled to a temperature lower than the resin film Tg. Finally, the stamper is released from the resin film on the substrate. In this way, a relief pattern can be formed in resin film on a substrate.

As a method of forming a stamper for nanoimprinting, a method has been proposed in which a stamper substrate is prepared with a resin film formed thereupon, and a quartz mother die with a relief pattern formed using an EB lithography method is pressed against the resin film, to invert and transfer the relief pattern (see Japanese Patent Application Laid-open No. 2008-200997).

Further, recently UV nanoimprinting methods have been proposed in which UV light irradiation is used in place of the use of a temperature cycle. In a UV nanoimprinting method, a quartz glass stamper is pressed against a resin layer with UV hardening properties, the resist layer is hardened by irradiation with UV light from the stamper side, and by releasing the stamper from the resist layer, a resist layer having a relief pattern is formed.

Normally, substrate processing is subsequently performed. Initially, soft etching is used to remove the remaining film in the depression portions of the resin film in which the relief pattern has been formed, exposing the substrate surface in the depression portions. Next, the resin film pattern is used as a mask to perform substrate processing. For example, when performing processing of a magnetic layer in magnetic recording media, the pattern of a resin film is used as a mask to perform dry etching of the magnetic layer. By processing the magnetic layer of the magnetic recording media in the shape of the pattern, discrete track media, in which a plurality of recording tracks are magnetically independent, or patterned media, in which individual recording elements are magnetically independent, can be manufactured. Or, a resin film pattern can be used as a mask to perform etching, CVD or other processing of a Si or other substrate, to manufacture semiconductor devices.

Further, Japanese Patent Application Laid-open No. 2006-191089 discloses a method of manufacturing a manufacturing template for imprinting lithography, comprising a process of bringing imprintable media on a manufacturing template substrate into contact with a parent template, and causing an imprint to be formed in the media, a process of separating the parent template, a process of etching areas of reduced thickness and causing regions of the manufacturing template substrate to be exposed, and a process of etching the exposed regions and demarcating the manufacturing template.

There are two serious problems when applying the above-described nanoimprinting methods to processing of discrete track media, patterned media, and semiconductor devices.

The first problem is that there are limits to reducing the line widths of patterns. In particular, in magnetic recording media, higher recording densities per unit area are sought, and a smaller pitch for the relief pattern formed is better. Also, signals are only obtained from the protruding portions of the magnetic recording layer, and so the protruding portions cannot be made smaller than is necessary. Hence means of making the depression portions of the magnetic recording layer as fine as possible are sought. Using current EB lithography methods, 10 nm lines can be formed within an extremely small range of several millimeters on a side. However, in processing of ranges of 10 mm on a side and greater to cope with formation of actual devices, the limit is formation of 20 nm lines. This limit arises due to the limits of focusing the electron beam, the fact that in fine processing the power density is low so that processing times are lengthened, and the fact that as processing times are lengthened, shifts arising from external disturbances occur. Hence in the examples of manufacturing methods described above, there is a limit to the EB lithography methods used to form relief patterns in stampers or manufacturing templates, and so it is difficult to raise the recording density of the magnetic recording media obtained.

In response to this problem, a stamper manufacturing method has been proposed which at least has (a) a process of pressing a parent stamper having a relief pattern against a resist layer formed on the surface of a substrate, (b) a process of releasing the parent stamper, and transferring the relief pattern onto the resist layer, (c) a process of exposing the substrate in the depression portions of the resist layer in which the relief pattern is formed, and (d) a process of etching the exposed substrate, to form a relief pattern on the substrate (see Japanese Patent Application Laid-open No. 2008-126450). In process (d) of this method, the substrate is side-etched, and the protruding portions formed on the substrate are made narrow, to achieve reduced line widths of the pattern. However, in this method, substrate etching accompanied by side etching is essential. For example, when numerous stampers are to be manufactured from a parent stamper, substrate etching accompanied by side etching must be performed for each of the stampers. Consequently there is the concern that manufacturing costs per stamper will increase.

Further, in response to this same problem, a stamper manufacturing method has been proposed comprising a process of manufacturing a master having a relief shape on the surface; a process of covering the master surface with relief shape with a sacrificial layer, comprising any one among Ta, Ti, W, and Mo; a process, thereafter, of using electroforming to manufacture a stamper with the relief shape transferred from the master; a process of releasing the stamper and the sacrificial layer from the master; and, a process of using an etching method employing fluorine-system gas to remove the sacrificial layer covering the stamper (see Japanese Patent Publication Specification No. 4127688). In this method, a stamper is formed with the width of the protruding portions smaller than the width of the depression portions of the master. However, the sacrificial layer cannot easily be formed on the relief face of the master with uniform film thickness. When the side-face taper of the protruding portions of the master is close to 90° in particular, or when the width of the depression portions is comparatively large (that is, in the case of a high aspect ratio), a sacrificial layer is not formed on the protruding portion side faces of the master, and the advantageous result that the stamper protruding portion width is reduced by the film thickness of the sacrificial layer is diminished.

A second problem is the fact that a stamper fabricated using an EB lithography method is extremely expensive. As stated above, in the case of narrow-line processing the power density is low, so that a long processing time is required. Hence the expensive EB apparatus is occupied for a long period, so that from the standpoint of processing cost, the stamper becomes expensive. Further, in manufacturing of magnetic recording media or semiconductor devices using nanoimprinting, the stamper must be replaced every several thousand to several million nanoimprintings. This is because repeated nanoimprinting causes the stamper to be deformed, and the precision of the transferred relief pattern declines. Hence the amortized cost of the expensive stampers is carried over to the product unit cost.

With respect to this problem, casting and other techniques are being used to replicate stampers (see for example Japanese Patent Application Laid-open No. 9-157881).

In view of the above, it would be desirable to provide a manufacturing method for a stamper for nanoimprinting, which can accommodate higher integration levels in information recording media and semiconductor devices, can enable formation of finer patterns, and can be implemented inexpensively. In particular, it would be desirable to provide a manufacturing method for a stamper for magnetic recording media manufacture enabling higher signal strengths and higher S/N ratio signals.

### SUMMARY OF THE INVENTION

The invention was devised in light of the above problems, and provides a manufacturing method for a stamper for nanoimprinting, which can accommodate higher integration levels in information recording media and semiconductor devices, can enable formation of finer patterns, and can be implemented inexpensively. In particular, the invention provides a manufacturing method for a stamper for magnetic recording media manufacture enabling higher signal strengths and higher S/N ratio signals.

A first embodiment of the invention is directed to a method of manufacturing a stamper for nanoimprinting having a relief shape on a surface thereof, which has, at least, (a) a step of forming a metal thin film on the surface of a substrate; (b) a step of forming a resist layer on the surface of the metal thin film; (c) a step of forming a relief pattern in the resist layer in use of an electron beam lithography method; (d) a step of etching the metal thin film in imitation of the relief pattern in the resist layer, and forming a pattern-shaped metal mask; and, (e) a step of forming a relief pattern on the substrate in imitation of the metal mask; and which is characterized in that, in step (d), by side-etching the metal thin film, the width of the protruding portions formed in the substrate in step (e) are reduced to be less than the width of the depression portions of the relief pattern formed in step (c). Here, it is desirable that the amount of side etching of the metal thin film in step (d) be 1 nm or greater and 50 nm or less. Further, step (d) can be performed by an active-ion etching method using a gas mixture comprising chlorine and oxygen.

A second embodiment of the invention is directed to a method of manufacturing a plurality of stampers for nanoimprinting having a relief shape on a surface thereof, characterized in comprising (1) a step of forming a master stamper, according to the method of the first embodiment; (2) a step of using the master stamper, transferring the relief shape thereof and forming a plurality of mother stampers; and (3) a step of using each of the plurality of mother stampers, transferring the relief shapes thereof and manufacturing a plurality of stampers. Here, step (2) can be executed by electroforming, by nanoimprinting, or by injection molding. Also, step (3) can be executed by electroforming, by nanoimprinting, or by injection molding. A method of manufacturing this embodiment can further comprise (4) a step of transferring the relief shape of a stamper and forming a plurality of mother stampers, and (5) a step of using each of the plurality of mother stampers obtained in step (4) to transfer the relief shapes thereof and manufacture a plurality of stampers; and steps (4) and (5) can be repeated one or more times. Here, the stamper used in step (4) can be a stamper formed in either step (3) or the step (5).

By means of the invention, a stamper having a relief pattern in which the width of protruding portion is reduced and moreover the width of depression portions is enlarged can be formed simply, without modifying the pitch, or the widths of lines and spaces, of a line and space pattern formed using an EB lithography method. The stamper obtained can precisely manufacture finely machined devices through use in a nanoimprinting process in formation of semiconductor devices, processing of magnetic recording media, and similar. In particular, when using a nanoimprinting method in processing of magnetic recording media, magnetic recording media can be manufactured with the width of the lines (protruding portions) which are recording portions enlarged, so that a higher signal intensity and signals with a higher S/N ratio are obtained, without modifying the pitch.

### BRIEF DESCRIPTION OF THE DRAWINGS

The invention will be described with reference to certain preferred embodiments thereof and the accompanying drawings, wherein:

FIGS. 1A to 1G show the stamper manufacturing method of a first embodiment of the invention, in which 1A through 1G show individual processes;

FIGS. 2A to 2G show manufacturing processes for magnetic recording media using a stamper manufactured by the manufacturing method of the first embodiment of the invention, in which 2A through 2G show individual processes; and

FIGS. 3A to 3F show the stamper manufacturing method of a second embodiment of the invention, in which 3A through 3F show individual processes.

### DESCRIPTION OF THE PREFERRED EMBODIMENTS

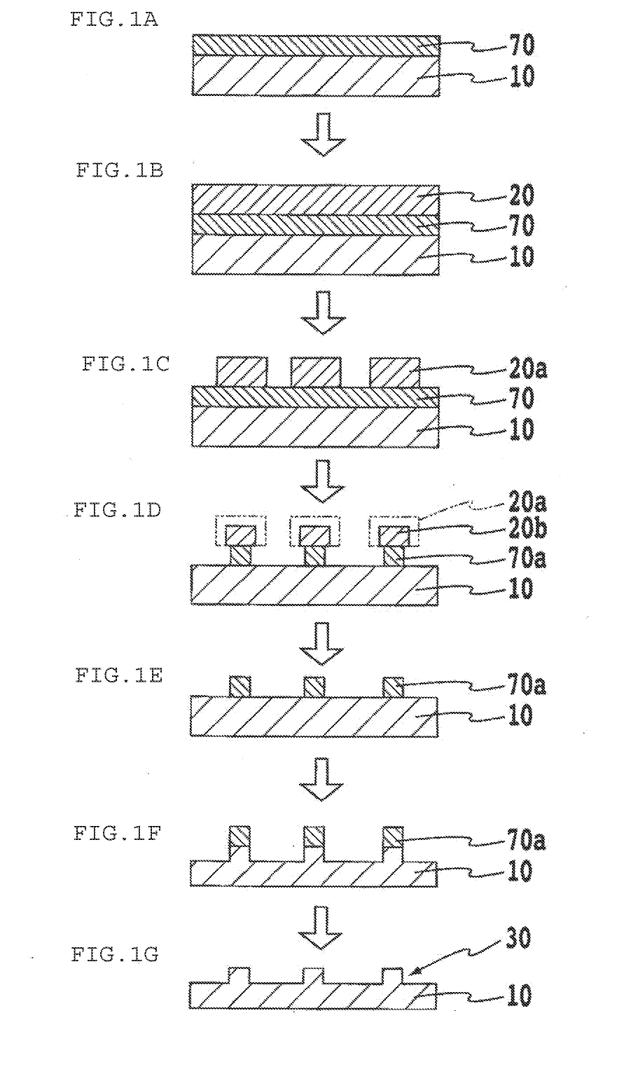

Referring to FIG. 1, the method of manufacturing a stamper for nanoimprinting having a relief shape on the surface, in accordance with a first embodiment of the invention, is explained. The method of manufacturing a stamper for nanoimprinting of this embodiment has at least:

(a) a process of forming a metal thin film on the surface of a substrate formed of Si or SiO₂;

(b) a process of forming a resist layer on the surface of the metal thin film;

(c) a process of forming a relief pattern in the resist layer, using an electron beam lithography method;

(d) a process of etching the metal thin film in imitation of the relief pattern in the resist layer, and of forming a pattern-shaped metal mask; and

(e) a process of forming a relief pattern on the substrate in imitation of the metal mask; the method is characterized in that, wherein in the process (d), the metal thin film is side-etched, such that the width of the protruding portions formed in the substrate in the process (e) are reduced from the width of the depression portions of the relief pattern formed in the process (c).

First, the substrate 10 is prepared. The substrate 10 can be formed using an inorganic material such as Si or SiO₂ (for example quartz); a metal such as Cu, Ni or similar, or an alloy of these; polydimethyl siloxane (PDMS), a polyimide, a polyamide, a polycarbonate, an epoxy resin, or another polymer material. When forming a stamper for thermal nanoimprinting, it is desirable that a material be used which is not deformed at the temperature and pressure employed during stamping. When forming a stamper for UV nanoimprinting, it is desirable that a material be used which transmits UV light. Here, when forming a stamper for UV nanoimprinting, the portions which become protruding portions (lines) of the stamper obtained may be formed using a material which does not transmit UV light. A material which does not transmit UV light in the protruding portions (lines) is effective for suppressing variation in the dimensions of the relief pattern of the object for transfer (imprint) due to bending-around of UV light.

Next, as shown in FIG. 1A, the metal thin film 70 is formed on the surface of the substrate 10. The metal thin film 70 can for example be formed using Cr, Ti, or similar. The film thickness of the metal thin film 70 depends on the pattern dimensions of the resist mask 20a (described below), and on the film thickness of the resist layer 20 for EB lithography. For example, when forming a resist mask 20a having a pattern with line (protruding portion) widths of 25 to 100 nm, a film thickness for the metal thin film 70 in the range 1 to 10 nm is preferable.

Next, as shown in FIG. 1B, the resist layer 20 for EB lithography is formed on the metal thin film 70. The resist layer 20 can be formed by applying a commercially marketed resist material for EB lithography using, for example, spin coating, dip coating, or similar. The resist material for EB lithography used may be a positive or a negative resist. The film thickness of the resist layer 20 depends on the pattern dimensions of the resist mask 20a (described below), and on the development precision and similar. For example, when forming a resist mask 20a having a pattern with line (protruding portion) widths of 25 to 100 nm, a film thickness for the resist layer 20 in the range 25 to 100 nm is preferable.

Next, as shown in FIG. 1C, an EB lithography method is used to pattern the resist layer 20, to form the resist mask 20a. The resist layer 20 is exposed to an electron beam along a prescribed pattern, and either the exposed portion of the resist layer 20 (in the case of positive resist), or the unexposed portion (in the case of negative resist), is removed by developer fluid, rinse cleaning is performed, and a resist pattern original plate on which is formed a resist mask 20a with the prescribed pattern is obtained. The pattern of the resist mask 20a depends on the magnetic recording media or semiconductor devices to be manufactured. For example, when forming a stamper for use in manufacturing discrete track media, it is desirable that the pattern have line (protruding portion) widths of 25 to 100 nm, positioned at a pitch corresponding to the track pitch.

Next, as shown in FIG. 1D, the metal thin film 70 is patterned in imitation of the resist mask 20a of the resist pattern original plate, to form the metal mask 70a. Patterning of the metal thin film 70 can be performed by reactive ion etching (RIE) using a gas mixture of a chlorine-based gas and oxygen as the reactive gas. Chlorine-based gases which can be used include CCl₄, SiCl₄, HCl, Cl₂, and similar. At this time, together with etching of the metal thin film 70, etching of the resist mask 20a also proceeds, and at the time this process ends, there is the possibility that a resist mask 20b is obtained with reduced dimensions.

In this process, the RF (high-frequency power supply) power, substrate bias voltage, reactive gas flow rate, vacuum pressure, etching time, etching temperature, and other etching conditions used are selected, and side etching of the metal thin film 70 is also performed. For example, a reactive gas pressure of 0.01 to 10 Pa, and in particular 0.1 to 1 Pa, a temperature of 25 to 100° C., an etching time of 10 seconds to 3 minutes, and similar can be adopted. In order to increase the amount of side etching, the pattern width of the metal mask 70a is reduced, and the interval between patterns is increased. The pattern width of the metal mask 70a corresponds to the width of the depression portions (spaces) of the stamper which is finally obtained. Hence an increase in the side etching amount causes the width of protruding portions (lines) to be expanded, and causes the widths of depression portions (spaces) to be reduced, in the stamper which is finally obtained. In this invention, by controlling the pattern of the resist mask 20a formed by the EB lithography method and the amount of side etching of the metal thin film 70, a stamper 30 having the desired line (protruding portion) width and space (depression portion) width can be obtained. In this invention, the “amount of side etching” is the difference between the line (protruding portion) width of the resist mask 20a prior to etching, and the width line (protruding portion) width of the metal mask 70a obtained after etching. For example, in a case in which the resist mask 20a has a pattern with a line (protruding portion) width of 25 to 100 nm, it is desirable that the side etching amount be 1 nm or greater and 50 nm or less.

Next, as shown in FIG. 1E, the remaining resist mask 20b is removed. Removal of the resist mask 20b can be performed using arbitrary means known in the art. When the width of the pattern of the remaining resist mask 20b is equal to or less than the width of the pattern width of the metal mask 70a, removal of the resist mask 20b may be omitted.

Next, as shown in FIG. 1F, a relief pattern is formed in the surface of the substrate 10 by RIE of the substrate 10, in imitation of the metal mask 70a. In this RIE process, a fluorine-based reactive gas comprising SF₆, CF₄ or CHF₃ is used, and side etching of the substrate 10 is avoided. Together with selection of the reactive gas used, it is preferable that the RF (high-frequency power supply) power, reactive gas flow rate, vacuum pressure, etching time, etching temperature, and other etching conditions are controlled so that side etching is suppressed. This is because side etching of the substrate 10 causes a decline in the perpendicularity of the protruding portion side walls of the relief pattern with respect to the surface of the substrate 10. A decline in the perpendicularity causes the protruding portions of the relief pattern to have a tapered shape in which the peak portion width is narrower than the bottom portion width, or an anchor shape in which the center portion width is narrower than the bottom portion width and the peak portion width. If a stamper having protruding portions with a taper shape or an anchor shape is used in nanoimprinting, these shapes are transferred into the resin film of the object for transfer (imprint), and as a result the variation in the pattern dimensions of the final products (magnetic recording media or semiconductor devices) is increased.

Finally, as shown in FIG. 1G, plasma etching using a chlorine-based gas is employed to remove the metal mask 70a, to obtain the stamper 30.

A second embodiment of the invention relates to a method of manufacturing a plurality of stampers for nanoimprinting, by replication using a stamper manufactured in the first embodiment as a master stamper. This embodiment is a method of manufacturing a plurality of stampers for nanoimprinting having a relief shape on the surface, and is characterized in comprising (1) a process of forming a master stamper, according to the method of the first embodiment; (2) a process of using the master stamper, transferring the relief shape thereof and forming a plurality of mother stampers; and (3) a process of using each of the plurality of mother stampers, transferring the relief shapes thereof and manufacturing a plurality of stampers.

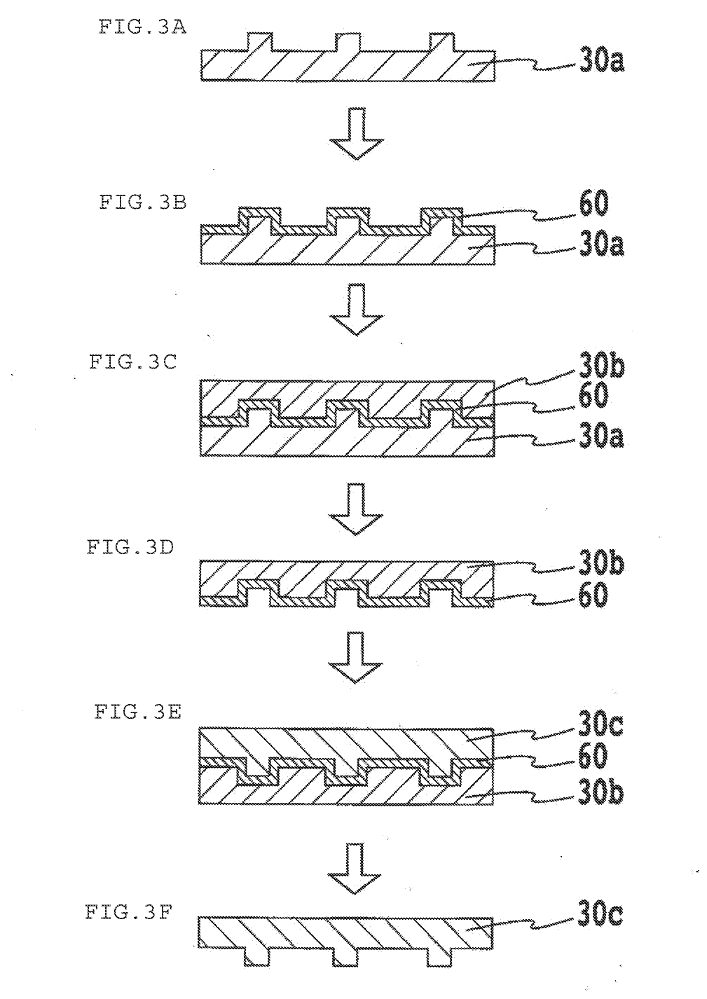

Below, an example of execution of the processes (2) and (3) using an electroforming method is explained, referring to FIG. 3. First, as shown in FIG. 3A, the method of the first embodiment is used to manufacture a stamper, which is used as the master stamper 30a.

Next, as shown in FIG. 3B, a conductive layer 60 is formed on the surface of the master stamper 30a. The conductive layer 60 can be formed using electroless plating, sputtering, or another method. The conductive layer 60 can be formed using an arbitrary material having conductive properties. Here, when executing the process (2) employing an electroforming method using a metal comprising Ni, it is preferable that the conductive layer 60 also be formed using a metal comprising Ni.

Next, as shown in FIG. 3C, the electroforming method is used to form the mother stamper 30b, while transferring the relief shape of the master stamper 30a. Materials which can be used in the electroforming method include metals comprising Ni, and other arbitrary materials known in the art.

Next, as shown in FIG. 3D, the master stamper 30a is removed, and a mother stamper 30b having the conductive layer 60 on the surface is obtained. The mother stamper 30b having the conductive layer 60 has a relief pattern which is the inversion of the relief pattern of the master stamper 30a.

Next, as shown in FIG. 3E, the electroforming method is used to form a replicated stamper 30c, while transferring the relief shape of the mother stamper 30b having the conductive layer 60. Finally, as shown in FIG. 3F, the conductive layer 60 and mother stamper are removed, and a replicated stamper 30c is obtained. The replicated stamper 30c has the same relief pattern as the master stamper 30a.

In the method of this embodiment, a plurality of mother stampers 30b are formed from one master stamper 30a, and a plurality of replicated stampers 30c can be formed from each of the mother stampers 30b thus obtained. Hence the method of this embodiment can be used to form numerous replicated stampers 30c by using an EB lithograph method only once to form the master stamper 30a, and so is effective for lowering the stamper manufacturing cost.

As necessary, replicated stampers 30c obtained by the method of manufacturing the second embodiment may be used as master stampers 30a, and the manufacturing method of the second embodiment may be repeated. That is, repetition one or more times of (4) a process of using a stamper obtained in the process (3) and transferring the relief shape to form a plurality of mother stampers, and of (5) a process of using each of the plurality of mother stampers obtained in the process (4) to transfer the relief shapes thereof and replicate a plurality of stampers, can be executed to obtain a still greater number of replicated stampers 30c. In the process (4), stampers obtained in the process (5) may be used.

In the above explanation, electroforming was used as an example of the method of formation of the mother stampers 30b in the process (2). However, the mother stampers 30b can be formed using a nanoimprinting method or an injection molding method.

When using a nanoimprinting method, the master stamper 30a is pressed against a substrate formed from a resin which can be employed in nanoimprinting, and a mother stamper 30b can be obtained. Or, a master stamper 30a can be pressed against a layered substrate, having a substrate of the above-described inorganic materials, metals, alloys, or polymer materials, and a film of a resin which can be employed in nanoimprinting formed thereupon, to transfer the relief pattern onto the resin film, after which etching is performed in imitation of the relief pattern transferred to the resin film to form the relief pattern on the substrate, so that a mother stamper 30b can be obtained.

When using an injection molding method, the master stamper 30a is positioned within the mold with the relief pattern facing the side of the space to be filled in the mold, and then an appropriate resin material is injected into the mold, so that a mother stamper 30b can be obtained.

Further, in forming a replicated stamper 30c in the process (3), a nanoimprinting method or an injection molding method can be used. The nanoimprinting method and the injection molding method can be executed by procedures similar to those described above.

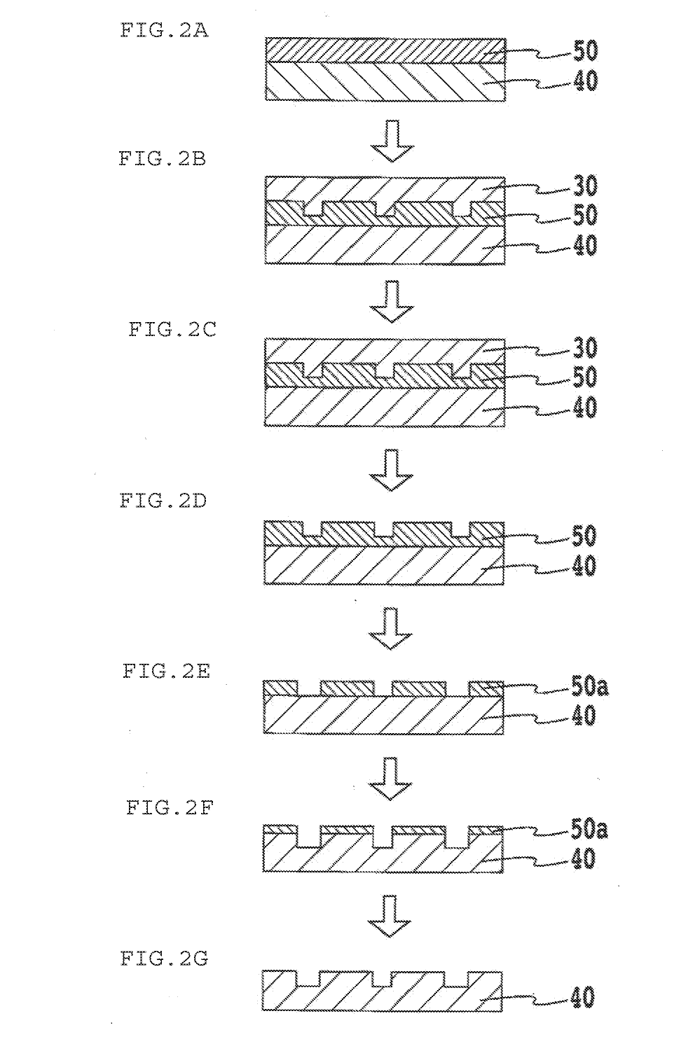

A stamper 30 obtained by the method of manufacturing the first embodiment explained above, or a replicated stamper 30c obtained by the method of manufacturing the second embodiment, can be used to manufacture magnetic recording media or semiconductor devices using a nanoimprinting method. Below, a method of manufacturing discrete track media using a stamper obtained by a method of manufacturing this invention is explained, referring to FIG. 2.

First, as shown in FIG. 2A, a resin-applied substrate, with a resin film 50 applied onto magnetic recording media 40 having at least a magnetic layer, is prepared. The magnetic recording media 40 may comprise, in addition to the magnetic layer, an underlayer, a soft magnetic backing layer, an intermediate layer, and/or a protective layer. As shown in FIG. 2, when employing a thermal nanoimprinting method, polymethyl methacrylate (PMMA) or another thermoplastic resin, or an epoxy resin or other thermosetting resin, can be used to form the resin film 50. Or, when employing a UV nanoimprinting method, a UV hardening resin can be used to form the resin film 50. Formation of the resin film 50 can be executed using spin coating, dip coating, or another arbitrary application method known in the art.

Next, as shown in FIG. 2B, the face of a stamper 30 on which is formed a relief pattern is pressed against the resin film 50 of the resin-applied substrate, and a relief pattern is formed in the resin film 50 in imitation of the relief pattern of the stamper 30. Prior to pressing, it is preferable that the face of the stamper 30 on which the relief pattern is formed be subjected to surface treatment with a release agent. When the resin film 50 is formed using a thermosetting resin or a UV hardening resin, heat treatment or UV irradiation is performed in the state in which the stamper 30 is pressed there against, to harden the resin film 50.

Next, as shown in FIG. 2C, the stamper 30 is released, and a resin-applied substrate having a resin film 50 to which the relief pattern has been transferred is obtained.

Next, as shown in FIG. 2D, the resin remaining in the depression portions of the resin film 50 is removed to expose the magnetic recording media 40, to form a resin mask 50a. Removal of resin can be executed by dry etching. In this process, a portion of the upper-face side of protrusions portions of the resin film 50 may be removed, so long as the position and width of the protrusion portions of the resin film 50 are maintained.

Next, as shown in FIG. 2E, the magnetic recording media 40 is etched in imitation of the resin mask 50a. Etching of the magnetic recording media 40 can for example be executed by RIE or other reactive etching methods. In this process, at least a portion of the magnetic layer in the magnetic recording media 40 is etched and removed, to form a plurality of magnetically independent recording tracks. When the magnetic recording media 40 comprises layers other than the magnetic layer, layers other than the magnetic layer may be etched, so long as a plurality of magnetically independent recording tracks are formed.

Finally, as shown in FIG. 2G, the remaining resin mask 50a is removed, so that magnetic recording media having a plurality of magnetically independent recording tracks can be obtained. As explained above, by subjecting the surface of magnetic recording media in which a magnetic layer is uniformly deposited to nanoimprinting by a stamper manufactured by a method of this invention and to processing by dry etching, magnetic recording media can be formed having a patterned magnetic layer, having protruding portions formed by the transfer of depression portions in the stamper.

In the above, a method of manufacturing discrete track media has been explained referring to FIG. 2; however, by modifying the relief pattern of the stamper 30, the above-described method can be employed in the manufacturing patterned media as well.

### Practical Example 1

First, an annular-shape quartz glass substrate 10, having an outer diameter of 65 mm and an inner diameter of 20 mm, was prepared. On the substrate 10, a metal thin film 70 comprising Cr with a film thickness of 10 nm was formed by a sputtering method.

Next, an electron beam drawing resist (ZEP520A manufactured by Zeon Corp.) was applied onto the surface of the metal thin film 70. Then, pattern exposure by an electron beam was performed, and a developing fluid (ZEP-RD manufactured by Zeon Corp.) was used to perform development according to EB lithography methods, to form a resist mask 20a. The resist mask 20a had concentrically circular lines and spaces as principal portions, and had a pattern comprising a servo information pattern in one portion. As a result of observations by the scanning electron microscope method, the pattern of concentrically circular lines and spaces which were the principal portions of the resist mask 20a had a line width of 50 nm and a space width of 50 nm. The film thickness of the line portions of the resist mask 20a was 75 nm.

Next, etching of the metal thin film 70 was performed, accompanied by side etching, in imitation of the resist mask 20a, to obtain a metal mask 70a. Etching was executed by RIE, using as the reactive gas a gas mixture of 50% Cl₂ gas and 50% O₂ gas. The RIE conditions were an RF power of 200 W, bias of 30 W, reactive gas pressure of 1.0 Pa, temperature of 80° C., and etching time of 15 seconds. Under these conditions, the amount of side etching of the metal thin film 70 was 20 nm.

Next, etching of the substrate 10 was performed in imitation of the metal mask 70a, to form a relief pattern on the substrate 10. Etching was executed by RIE, using as the reactive gas a gas mixture of 60% CHF₃ gas and, as the deposition gas, 40% C₄F₈. The RIE conditions were set to an RF power of 200 W, bias of 30 W, reactive gas pressure of 0.05 Pa, temperature of 25° C., and etching time of 40 seconds.

Next, the resist mask 20b remaining was removed by etching using oxygen plasma. Also, ion beam etching using Ar gas was performed to remove the metal mask 70a, to obtain a stamper 30.

The principal portions (portions other than the servo information pattern) of the relief pattern on the stamper 30 comprised concentrically circular lines (protruding portions) 30 nm in width and 60 nm in height, and spaces (depression portions) of width 70 nm.

By performing evaporation deposition of a thin film raw material having hydrophilic functional groups (Optool HD1101 manufactured by Daikin Industries) onto the surface of the relief pattern of the stamper 30 thus obtained, a monolayer release film was formed.

Next, as the uppermost layer of the magnetic layer, a UV hardening resin (PAK-01 by Toyo Gosei) was applied by spin coating onto annular-shape magnetic recording media 40 with outer diameter 65 mm and inner diameter 20 mm, and baking at 80° C. was performed to form a resin film 50 of film thickness 50 to 100 nm, to obtain a resin-applied substrate.

The face of the stamper 30 having the relief pattern was brought into contact with the resin film 50 of the resin-applied substrate, and was pressed with a pressure of 0.1 MPa to cause close contact. In this state, irradiation with UV light was performed from the side of the stamper 30 for ten seconds. Next, the stamper 30 was removed, and a resin-applied substrate having a resin film 50 to the surface of which was transferred a relief pattern was obtained. Then, etching was performed using oxygen plasma to remove the resin remaining in the depression portions of the resin film 50, and a resin mask 50a was formed.

Next, RIE using chlorine gas was employed to etch the magnetic layer under conditions in which side etching of the magnetic layer did not occur, and a magnetic layer was obtained having a pattern comprising concentrically circular lines and spaces as principal portions and a servo information pattern. The principal portions of the relief pattern of the magnetic layer comprises lines of width 70 nm and spaces of width 30 nm. By the procedure described above, it was possible to form a pattern in which, with a pitch of 100 nm, the ratio of the widths of lines (recording tracks) to the widths of spaces (gaps between tracks) was 2:1 or greater; such a pattern is difficult to form using methods of the prior art.

Then, the remaining resin mask 50a was removed by ashing using oxygen plasma, and a CVD method was used to form a protective layer comprising diamond-like carbon (DLC) on the magnetic layer, after which the dip coating method was used to form a liquid lubricant layer.

By the procedure described above, discrete track media was obtained, having, on an entire annular face with an outer diameter of 65 mm and an inner diameter of 20 mm, a pattern comprising as principal portions lines and spaces with line widths of 70 nm and space widths of 30 nm, and comprising a servo information pattern in one portion.

### Practical Example 2

Except for changing the conditions for etching the metal thin film 70 during stamper formation to a reactive gas pressure of 0.2 Pa, temperature of 50° C., and etching time of 18 seconds, a procedure similar to that of Practical Example 1 was repeated, to form a stamper 30 the principal portions of which were lines and spaces comprising concentrically circular lines (protruding portions) of width 40 nm and height 60 nm, and spaces (depression portions) of width 60 nm. That is, the side etching amount of the metal thin film 70 under the above conditions was 10 nm.

A procedure similar to that of Practical Example 1 was used to perform nanoimprinting using the stamper thus obtained and etching, to obtain discrete track media, having, on an entire annular face with an outer diameter of 65 mm and an inner diameter of 20 mm, a pattern comprising as principal portions lines and spaces with line widths of 60 nm and space widths of 40 nm, and comprising a servo information pattern in one portion.

### Comparative Example 1

Except for changing the conditions for etching the metal thin film 70 during stamper formation to a reactive gas pressure of 0.05 Pa, temperature of 25° C., and etching time of 22 seconds, a procedure similar to that of Practical Example 1 was repeated, to form a stamper 30 the principal portions of which were lines and spaces comprising concentrically circular lines (protruding portions) of width 50 nm and height 60 nm, and spaces (depression portions) of width 50 nm. That is, under the above etching conditions, side etching of the metal thin film 70 was not performed.

A procedure similar to that of Practical Example 1 was used to perform nanoimprinting using the stamper thus obtained and etching, to obtain discrete track media, having, on an entire annular face with an outer diameter of 65 mm and an inner diameter of 20 mm, a pattern comprising as principal portions lines and spaces with line widths of 50 nm and space widths of 50 nm, and comprising a servo information pattern in one portion.

Evaluations

The signal strengths and S/N ratios of on-track magnetic recording signals for discrete track media manufactured in Practical Examples 1 and 2 and in Comparative Example 1 were measured. As a result, signals could be obtained for all media. Also, the greater the line width of the magnetic layer, the greater was the strength of the signal obtained, and the more the S/N ratio was improved.

### Practical Example 3

A stamper was manufactured by a procedure similar to that of Practical Example 1, and was used as master stamper 30a. Next, a sputtering method was used to form a conductive layer 60 comprising Ni of film thickness 5 nm on the surface of the master stamper 30a.

Next, Ni electroforming was performed based on the master stamper 30a with the conductive layer 60 formed, and a mother stamper 30b of thickness 300 μm was obtained. Then, by using the edges of the Ni electroformed object as starting points and pulling away from the master stamper 30a, release at the interface of the master stamper 30a and the conductive layer 60 was achieved, to remove the master stamper 30a.

Next, Ni electroforming was performed based on the layered member of the conductive layer 60 and the mother stamper 30b, and a replicated stamper 30c of thickness 300 μm was obtained. Then, by using the edges of the Ni electroformed object as starting points and pulling away from the replicated stamper 30c, release at the interface of the replicated stamper 30c and the conductive layer 60 was achieved, to isolate the replicated stamper 30c.

As a result of SEM observations, the replicated stamper 30c obtained clearly had the same relief pattern as the master stamper 30a, the principal portions of which were lines and spaces comprising concentrically circular lines (protruding portions) of width 40 nm and height 60 nm, and spaces (depression portions) of width 60 nm, and comprising a servo information pattern in one portion.

Using the replicated stamper 30c thus obtained, nanoimprinting of the resin-applied substrate used in Practical Example 1 was performed, employing a procedure similar to that of Practical Example 1. As a result of inspections of the shape of the resin film obtained, there was little taper shape in the protruding portions of the resin film, and a pattern with high dimensional precision was obtained. The relief patterns of the resin films obtained in this practical example were the same as the relief patterns of the resin films obtained in Practical Example 1 (that is, the pattern obtained in nanoimprinting using the master stamper 30a).

The invention has been described with reference to certain preferred embodiments thereof. It will be understood, however, that modifications and variations are possible within the scope of the appended claims.

This application is based on, and claims priority to, Japanese Patent Application No: 2009-138202, filed on Jun. 9, 2009. The disclosure of the priority application, in its entirety, including the drawings, claims, and the specification thereof, is incorporated herein by reference.

What is claimed is:

1. A method of manufacturing a stamper for nanoimprinting having a relief shape on a surface thereof, the method comprising the steps of:
(a) forming a metal thin film on a surface of a substrate;
(b) forming a resist layer on a surface of the metal thin film;
(c) forming a relief pattern in the resist layer in use of an electron beam lithography method;
(d) etching the metal thin film in imitation of the relief pattern in the resist layer, and forming a metal mask; and
(e) forming a relief pattern on the substrate in imitation of the metal mask,
wherein in step (d), by side-etching the metal thin film, a width of protruding portions formed in the substrate in step (e) are reduced to be less than a width of depression portions of the relief pattern formed in step (c).

2. The method of manufacturing a stamper for nanoimprinting according to claim 1, wherein an amount of side etching of the metal thin film in step (d) is 1 nm or greater and 50 nm or less.

3. The method of manufacturing a stamper for nanoimprinting according to claim 1, wherein step (d) is performed by a reactive-ion etching method in use of a gas mixture containing chlorine and oxygen.

4. A method of manufacturing a plurality of stampers for nanoimprinting having a relief shape on a surface thereof, the method comprising the steps of:
(1) forming a master stamper, according to a method comprising the steps of: (a) forming a metal thin film on a surface of a substrate; (b) forming a resist layer on a surface of the metal thin film; (c) forming a relief pattern in the resist layer in use of an electron beam lithography method; (d) etching the metal thin film in imitation of the relief pattern in the resist layer, and forming a metal mask; and (e) forming a relief pattern on the substrate in imitation of the metal mask, wherein in step (d), by side-etching the metal thin film, a width of protruding portions formed in the substrate in step (e) are reduced to be less than a width of depression portions of the relief pattern formed in step (c);
(2) using the master stamper, transferring the relief shape thereof and forming a plurality of mother stampers; and,
(3) using each of the plurality of mother stampers, transferring the relief shapes thereof and manufacturing a plurality of stampers.

5. The method of manufacturing a plurality of stampers for nanoimprinting according to claim 4, wherein step (2) is executed by electroforming, by nanoimprinting, or by injection molding.

6. The method of manufacturing a plurality of stampers for nanoimprinting according to claim 4, wherein step (3) is executed by electroforming, by nanoimprinting, or by injection molding.

7. The method of manufacturing a plurality of stampers for nanoimprinting according to claim 4, further comprising the steps of:
(4) transferring the relief shape of a stamper and forming a plurality of mother stampers; and
(5) using each of the plurality of mother stampers obtained in step (4) to transfer the relief shapes thereof and manufacture a plurality of stampers,
wherein the stamper used in step (4) is the stamper obtained in either step (3) or in step (5), and the steps (4) and (5) are repeated one or more times.

8. The method of manufacturing a plurality of stampers for nanoimprinting according to claim 4, wherein an amount of side etching of the metal thin film in step (d) is 1 nm or greater and 50 nm or less.

9. The method of manufacturing a plurality of stampers for nanoimprinting according to claim 4, wherein step (d) is performed by a reactive-ion etching method in use of a gas mixture containing chlorine and oxygen.
